(19) United States
(12) Patent Application Publication
(10) Pub. No.: US 2008/0012014 A1
(43) Pub. Date: Jan. 17, 2008

(54) Thin film transistor, method of preparing the same, and flat panel display device including the thin film transistor

(76) Inventors: Jin-Seong Park, Suwon-si (KR); Min-Chul Suh, Suwon-si (KR)

Correspondence Address: Robert E. Bushnell, Suite 300, 1522 K Street, N.W., Washington, DC, 20005-1202, US

(21) Appl. No.: 11/819,966

(22) Filed: Jun. 29, 2007

(30) Foreign Application Priority Data
Jul. 14, 2006 (KR) 10-2006-0066270
Aug. 10, 2006 (KR) 10-2006-0075833

(51) Int. Cl. H01L 51/10; H01L 51/40

(52) U.S. Cl. 257/40; 438/99; 257/E51.006

(57) ABSTRACT

A thin film transistor (TFT) has reduced contact resistance between an organic semiconductor layer and source and drain electrodes. In the TFT, organic semiconductor crystals can be grown satisfactorily so as to improve electrical properties of the TFT. A method of preparing the same and a flat panel display device including the TFT are disclosed.

### CLAIM OF PRIORITY

This application makes reference to, incorporates the same herein, and claims all benefits accruing under 35 U.S.C. §119 from applications earlier filed in the Korean Intellectual Property Office on Jul. 14, 2006 and there duly assigned Serial No. 10-2006-0066270 and on the 10 Aug. 2006 and there duly assigned Serial No. 10-2006-0075833.

### BACKGROUND OF THE INVENTION

1. Technical Field

The present invention relates to a thin film transistor (TFT), a method of preparing the same, and a flat panel display device including the TFT. More particularly, the present invention relates to a TFT having reduced contact resistance between an organic semiconductor layer and source and drain electrodes, and in which organic semiconductor crystals can be grown satisfactorily so as to improve electrical properties of the TFT, a method of preparing the same, and a flat panel display device including the TFT.

2. Related Art

Thin film transistors (TFTs) which are used in flat panel display devices, such as liquid crystal display devices (LCDs), organic light emission display devices, inorganic light emission display devices, and the like, are used as switching devices for controlling pixel operations and as driving devices for operating pixels.

TFTs include a semiconductor layer comprising source and drain regions and a channel region interposed between the source and drain regions, a gate electrode insulated from the semiconductor layer and located in a region corresponding to the channel region, and source and drain electrodes contacting the source and drain regions, respectively.

Organic TFTs include an organic semiconductor layer composed of an organic semiconductor material, and can be manufactured at low temperatures. Thus, a plastic substrate can be used. Due to these advantages of organic TFTs, research into organic TFTs has recently been conducted. For example, Korean Patent Publication No. 2004-0012212 discloses an organic TFT.

However, in an organic TFT, ohmic contact is not easily achieved between a source/drain electrode material and an organic semiconductor layer material due to a work function difference. Therefore, the contact resistance may be heightened between an organic semiconductor layer and source and drain electrodes so as to lower electrical properties of the TFT. When an organic semiconductor layer is formed on source and drain electrodes, the organic semiconductor crystals can be grown to have a satisfactory grain size which can also contribute to lowering electrical properties of the TFT.

### SUMMARY OF THE INVENTION

The present invention provides a thin film transistor (TFT) having interface properties to improve the contact resistance between an organic semiconductor layer and source and drain electrodes; and to facilitate growth of organic semiconductor crystals, a method of preparing the same and a flat panel display device including the TFT.

According to an aspect of the present invention, a thin film transistor includes: a gate electrode; source and drain electrodes insulated from the gate electrode; an organic semiconductor layer which is insulated from the gate electrode, and which is electrically connected to the source and drain electrodes; an insulating layer which insulates the gate electrode from the source and drain electrodes or the organic semiconductor layer; and an intermediate layer formed between the organic semiconductor layer and the source and drain electrodes. The intermediate layer includes a first layer which reduce the contact resistance between the organic semiconductor layer and the source and drain electrodes, and a second layer which facilitates growth of organic semiconductor crystals of the organic semiconductor layer.

According to another aspect of the present invention, a method of manufacturing a thin film transistor includes: forming source and drain electrodes on a substrate; forming an intermediate layer on the source and drain electrodes; forming an organic semiconductor layer to be electrically connected to the source and drain electrodes; forming an insulating layer so as to cover the organic semiconductor layer; and forming a gate electrode so as to correspond to the source and drain electrodes; wherein the intermediate layer includes a first layer which reduces the contact resistance between the organic semiconductor layer and the source and drain electrodes, and a second layer which facilitates growth of organic semiconductor crystals of the organic semiconductor layer.

According to another aspect of the present invention, a method of manufacturing a thin film transistor includes: forming a gate electrode on a substrate; forming an insulating layer so as to cover the gate electrode; forming source and drain electrodes on the insulating layer; forming an intermediate layer on the source and drain electrodes; and forming an organic semiconductor layer to be electrically connected to the source and drain electrodes; wherein the intermediate layer includes a first layer which reduces the contact resistance between the organic semiconductor layer and the source and drain electrodes, and a second layer which facilitates growth of organic semiconductor crystals of the organic semiconductor layer.

According to another aspect of the present invention, a flat panel display device includes a thin film transistor on each of a plurality of pixels, and a pixel electrode contacting a source or drain electrode of the thin film transistor.

According to another aspect of the present invention, a thin film transistor includes: a gate electrode; source and drain electrodes insulated from the gate electrode; an organic semiconductor layer which is insulated from the gate electrode, and which is electrically connected to the source and drain electrodes; an insulating layer which insulates the gate electrode from the source and drain electrodes or the organic semiconductor layer; and an intermediate layer comprising a plurality of first regions which facilitate growth of organic semiconductor crystals of the organic semiconductor layer, and a plurality of second regions which reduce the contact resistance between the organic semiconductor layer and the source and drain electrodes.

According to another aspect of the present invention, a method of manufacturing a thin film transistor includes: forming source and drain electrodes on a substrate; forming an intermediate layer so as to cover the source and drain electrodes; forming an organic semiconductor layer on the intermediate layer; forming an insulating layer so as to cover the organic semiconductor layer; and forming a gate electrode so as to correspond to the source and drain electrodes; wherein the intermediate layer comprises a plurality of first regions which facilitate growth of organic semiconductor crystals of the organic semiconductor layer, and a plurality of second regions which reduce the contact resistance between the organic semiconductor layer and the source and drain electrodes.

According to another aspect of the present invention, a method of manufacturing a thin film transistor includes: forming a gate electrode on a substrate; forming an insulating layer so as to cover the gate electrode; forming source and drain electrodes on the insulating layer; forming an intermediate layer so as to cover the source and drain electrodes; and forming an organic semiconductor layer on the intermediate layer; wherein the intermediate layer comprises a plurality of first regions which facilitate growth of organic semiconductor crystals of the organic semiconductor layer, and a plurality of second regions which reduce the contact resistance between the organic semiconductor layer and the source and drain electrodes.

According to another aspect of the present invention, a flat panel display device includes a thin film transistor on each of a plurality of pixels, and a pixel electrode contacting a source or drain electrode of the thin film transistor.

In a TFT according to the present invention, the contact resistance is improved between an organic semiconductor layer and source and drain electrodes. In addition, the organic semiconductor crystals of the organic semiconductor layer are grown satisfactorily. Therefore, the TFT may have excellent electrical properties.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1 thru 4 are cross-sectional views illustrating structures of thin film transistors (TFTs) according to embodiments of the present invention;

FIG. 5 is a cross-sectional view illustrating an organic light emitting display device including a TFT according to an embodiment of the present invention;

FIGS. 6 and 7 are cross-sectional views illustrating structures of TFTs according to embodiments of the present invention;

FIGS. 8A thru 8C are cross-sectional views illustrating a method of manufacturing an intermediate layer of a TFT according to an embodiment of the present invention;

FIG. 9 is a cross-sectional view of an organic light emission display device including a TFT according to another embodiment of the present invention;

FIGS. 10 and 11 are graphs illustrating current-voltage characteristics of a TFT according to an embodiment of the present invention and a conventional TFT, respectively; and

FIGS. 12 and 13 are graphs illustrating current-voltage characteristics of a TFT according to another embodiment of the present invention and a conventional TFT, respectively.

### DETAILED DESCRIPTION OF THE INVENTION

Hereinafter, the present invention will be described in detail by explaining embodiments of the invention with reference to the attached drawings.

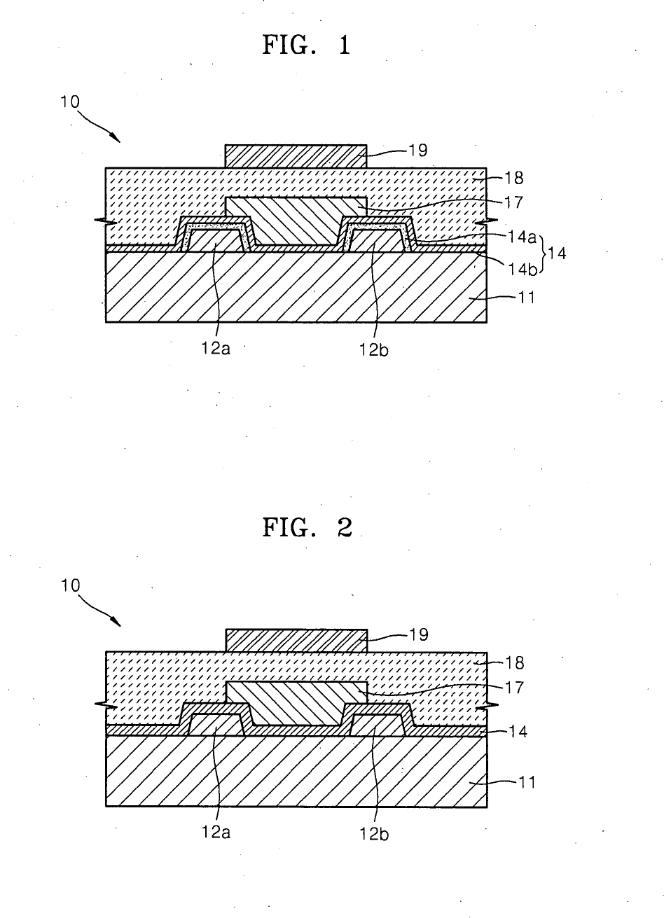

FIG. 1 is a cross-sectional view of a thin film transistor (TFT) according to an embodiment of the present invention.

Referring to FIG. 1, the TFT 10 includes a substrate 11, source and drain electrodes 12a and 12b, respectively, an intermediate layer 14, an organic semiconductor layer 17, an insulating layer 18 and a gate electrode 19 which are stacked upon one another in the above-mentioned order. The intermediate layer 14 includes a first layer 14a which reduces the contact resistance between the organic semiconductor layer 17 and the source and drain electrodes 12a and 12b, and a second layer 14b which facilitates growth of organic semiconductor crystals of the organic semiconductor layer 17.

In FIG. 1, the substrate 11 may be a conventional substrate, such as a glass, plastic, or metal substrate. The glass substrate may be formed of silicon oxide, silicon nitride, or the like. The plastic substrate may be formed of an insulating organic material. For example, the insulating organic material may be selected from the group consisting of polyethersulphone (PES), polyacrylate (PAR), polyetherimide (PEI), polyethylene napthalate (PEN), polyethyleneterephthalate (PET), polyphenylene sulfide (PPS), polyallylate, polyimide, polycarbonate (PC), triacetate cellulous (TAC) and cellulose acetate propionate (CAP), but the invention is not limited thereto. The metal substrate may include at least one selected from the group consisting of carbon, iron, chrome, manganese, nickel, titanium, molybdenum, stainless steel (SUS), an Invar alloy, a ZInconel alloy and a Kovar alloy, but the invention is not limited thereto. The metal substrate may be a metal foil. Here, in order to achieve flexibility, a plastic or metal substrate can be used for the substrate 11.

A buffer layer, a barrier layer, or an impurities diffusion inhibition layer may be formed on one surface or both surfaces of the substrate 11. In particular, when the substrate 11 is a metal substrate, an insulating layer (not shown) may be further formed on the substrate 11.

The source and drain electrodes 12a and 12b, respectively, are formed on the substrate 11. Non-limiting examples of a material used to form the source and drain electrodes 12a and 12b, respectively, include metals, such as Au, Pd, Pt, Ni, Rh, Ru, Ir, Os, Al and Mo, metal alloys of at least two metals, an Al:Nd alloy, an MoW alloy, metal oxides, such as ITO, IZO, NiO, Ag₂O, In₂O₃—Ag₂O, CuAlO₂, SrCu₂O₂ and Zr-doped ZnO, but they are not limited thereto. Combinations of two or more of the above metals or metal oxides can be used.

The organic semiconductor layer 17 is formed on the source and drain electrodes 12a and 12b, respectively, so as to be electrically connected to the source electrode 12a and drain electrode 12b. The intermediate layer 14 is interposed between the organic semiconductor layer 17 and the source and drain electrodes 12a and 12b, respectively. The intermediate layer 14 includes a first layer 14a which reduces the contact resistance between the organic semiconductor layer 17 and the source and drain electrodes 12a and 12b, respectively, and a second layer 14b which facilitates growth of the organic semiconductor crystals of the organic semiconductor layer 17.

The first layer 14a improves the contact resistance, which can be inferior due to a work function difference between the organic semiconductor layer 17 and the source and drain electrodes 12a and 12b, respectively. The first layer 14a can be formed using conventional methods and well-known materials to improve the contact resistance between the organic semiconductor 17 and the source and drain electrodes 12a and 12b, respectively. For example, the first layer 14a may be a self assembled monolayer (SAM). More particularly, the first layer 14a can be a SAM which is formed using 2-mercapto 5-nitrobenzimidazole (MNB), 2 mercapto-5-methoxy-benzimidazole (MMB), or 2-mercapto-benzoxazole (MBX) etc., but it is not limited thereto.

The second layer 14b, which facilitates growth of the organic semiconductor crystals of the organic semiconductor layer 17, is formed on the first layer 14a. When organic semiconductor crystals of the organic semiconductor layer 17 are small, resistance can be increased as the grain boundary of the crystalline structure gets bigger and the number of trap sites increases. However, when the organic semiconductor layer 17 is formed on the second layer 14b according to the current embodiment of the present invention, the organic semiconductor crystals can be grown satisfactorily and electrical properties of the TFT 10 can be improved.

The second layer 14b can be formed as an ultra thin layer having a thickness of less than 100 Å, preferably, 10 Å to 100 Å. When the thickness of the second layer 14b is equal to or greater than 10 Å, the second layer 14b can be formed so as to have a uniform thickness. When the thickness of the second layer 14b is equal to or less than 100 Å, the organic semiconductor 17 can be electrically connected with the source and drain electrodes 12a and 12b, respectively.

A contact angle of water on the second layer 14b is greater than a contact angle of water on the source and drain electrodes 12a and 12b, respectively. Thus, the organic semiconductor crystals on the second layer 14b can be grown to a satisfactory crystal size.

With the assumption that there is a liquid on a solid plane in air, the term “contact angle” indicates the angle between the tangent of the liquid and the tangent of the solid plane at a contact point of the liquid, the solid plane and the air. Here, it can be understood that the solid plane adsorbs liquid vapor.

A contact angle may be used as a measure of wetting of a solid plane by liquid. For example, a small contact angle indicates a high degree of wetting, for example, a hydrophilic property and a high surface energy, and a large contact angle indicates a low degree of wetting, for example, a hydrophobic property and a low surface energy.

The following methods may be used to measure the contact angle. These methods include: a method of measuring a contact angle by directly projecting the shape of a liquid drop onto a screen; a method of measuring the volume and height of a liquid droplet and the radius of a lower circle to calculate a contact angle with the assumption that the liquid droplet is considered as a partial sphere; methods of measuring a tilt angle and an adhesive tension of a solid plane in the state where a curved portion of a liquid droplet contacting the solid plane is positioned to form a horizontal plane and the solid plane is positioned above and perpendicular to the liquid droplet; and the like. The above-described definitions of the contact angle and contact angle measurement methods are known to those of ordinary skill in the art.

Throughout this specification, the contact angle of water on the second layer 14b or the source and drain electrodes 12a and 12b, respectively, refers to the measured contact angle of a liquid, which is water, on a solid plain surface, in this case, the second layer 14b or the source and drain electrodes 12a and 12b, respectively. According to an embodiment of the present invention, contact angles of water on the second layer 14b and the source and drain electrodes 12a and 12b, respectively, may be measured, for example, using a contact angle method using water. The contact angle method using water is a method of measuring the angle between the surface of a layer and a water droplet dropped on the layer in μl using a charge-coupled device (CCD) at a room temperature.

A contact angle of water on the second layer 14b is greater than a contact angle of water on the source and drain electrodes 12a and 12b, respectively. More particularly, the contact angle of water on the second layer 14b may be 10° thru 15° greater than the contact angle of water on the source and drain electrodes 12a and 12b, respectively. When the contact angle of water on the second layer 14b is 10° thru 15° greater than the contact angle of water on the source and drain electrodes 12a and 12b, respectively, satisfactory growth of the organic semiconductor crystals may be achieved.

For example, when the source and drain electrodes 12a and 12b, respectively, are formed of Au, the contact angle of water on the source and drain electrodes 12a and 12b, respectively, is 60° thru 70°. When the second layer 14b includes polymethylmethacrylate (PMMA), the contact angle of water on the second layer 14b may be 70° thru 80°. Therefore, when the organic semiconductor layer 17 is formed so as to be electrically connected to the source and drain electrodes 12a and 12b, respectively, with the second layer 14b interposed therebetween, the organic semiconductor crystals are larger than when the organic semiconductor layer 17 is formed so as to be electrically connected to the source and drain electrodes 12a and 12b, respectively, without the second layer 14b.

More particularly, the second layer 14b may include at least one selected from a group consisting of PMMA and polystyrene (PS), but it is not limited thereto.

The intermediate layer 14 is formed on the source and drain electrodes 12a and 12b, respectively, including the first layer 14a which reduces the contact resistance between the organic semiconductor layer 17 and the source and drain electrodes 12a and 12b, respectively, and the second layer 14b which facilitates growth of the organic semiconductor crystals of the organic semiconductor layer 17. Accordingly, the organic semiconductor layer 17 and the source and drain electrodes 12a and 12b, respectively, are electrically connected to the intermediate layer 14 interposed therebetween.

Examples of an organic semiconductor material for the organic semiconductor layer 17 include pentacene, tetracene, anthracene, naphthalene, a-6-thiophen, a-4-thiophen, perylene and a derivative thereof, rubrene and a derivative thereof, coronene and a derivative thereof, perylene tetracarboxylic diimide and a derivative thereof, perylene tetracarboxylic dianhydride and a derivative thereof, polythiophene and a derivative thereof, polyparaphenylene vinylene and a derivative thereof, polyparaphenylene and a derivative thereof, polyfluorene and a derivative thereof, polythiophene vinylene and a derivative thereof, a polythiophene-heterocyclic aromatic copolymer and a derivative thereof, olignaphthalene and a derivative thereof, oligothiophene of a-5-thiophene and a derivative thereof, a metal-containing or metal-free phthalocyanine and a derivative thereof, pyromellitic dianhydride and a derivative thereof, pyromellitic diimide and a derivative thereof, and the like. Combinations of two or more of these materials can be used.

The insulating layer 18 is formed so as to cover the organic semiconductor layer 17. The insulating layer 18 may be formed of an inorganic material such as a metal oxide or a metal nitride, or an organic material such as an insulating organic polymer, but the material of the insulating layer 18 is not limited thereto.

The gate electrode 19, which has a predetermined pattern, is formed on the insulating layer 18 so as to correspond to the source and drain electrodes 12a and 12b, respectively. The gate electrode 19 may be formed so as to overlap with a part of the source and drain electrodes 12a and 12b, respectively, but is not limited thereto. The gate electrode 19 may be formed of a metal or a metal alloy, such as Au, Ag, Cu, Ni, Pt, Pd, Al, Mo, an Al:Nd alloy, an MoW alloy, etc., but is not limited thereto.

FIG. 2 illustrates a TFT according to another embodiment of the present invention. An interface may not be apparent between a first layer 14a of FIG. 1 which reduces the contact resistance between the organic semiconductor layer 17 and the source and drain electrodes 12a and 12b, respectively, and a second layer 14b of FIG. 1 which facilitates growth of the organic semiconductor crystals of the organic semiconductor layer 17 as illustrated in FIG. 2. In FIG. 2, an intermediate layer 14 includes first and second layers similar to the first and second layers 14a and 14b, respectively, of FIG. 1, but the layer 14 is illustrated as one layer due to an inapparent interface between the first and second layers.

FIG. 3 is a cross-sectional view of a TFT according to another embodiment of the present invention. Referring to FIG. 3, the TFT 10 includes a substrate 11, a gate electrode 19, an insulating layer 18, source and drain electrodes 12a and 12b, respectively, an intermediate layer 14 and an organic semiconductor layer 17, which are stacked upon one another in the above-mentioned order. The intermediate layer 14 includes a first layer 14a which reduces the contact resistance between the organic semiconductor layer 17 and the source and drain electrodes 12a and 12b, respectively, and a second layer 14b which facilitates growth of organic semiconductor crystals of the organic semiconductor layer 17.

Each layer included in the TFT 10 of FIG. 3 corresponds to its equivalent layer in the TFT 10 of FIG. 1, and thus a detailed description thereof will be omitted.

FIG. 4 illustrates a TFT according to another embodiment of the present invention. An interface may also not be apparent between a first layer 14a of FIG. 3 which reduces the contact resistance between the organic semiconductor layer 17 and the source and drain electrodes 12a and 12b, respectively, and a second layer 14b of FIG. 3 which facilitates growth of the organic semiconductor crystals of the organic semiconductor layer 17 as illustrated in FIG. 4.

A TFT according to the present invention can be manufactured using a variety of methods.

A method of manufacturing the TFT according to an embodiment of the present invention may include: forming source and drain electrodes on a substrate; forming an intermediate layer on the source and drain electrodes; forming an organic semiconductor layer so as to be electrically connected to the source and drain electrodes; forming an insulating layer so as to cover the organic semiconductor layer; and forming a gate electrode so as to correspond to the source and drain electrodes; wherein the intermediate layer includes a first layer which reduces the contact resistance between the organic semiconductor layer and the source and drain electrodes, and a second layer which facilitates growth of organic semiconductor crystals of the organic semiconductor layer. Thus, a TFT, such as the TFT 10 of FIG. 1 or FIG. 2, may be manufactured.

A method of manufacturing the TFT according to another embodiment of the present invention may include: forming a gate electrode on a substrate; forming an insulating layer so as to cover the gate electrode; forming source and drain electrodes on the insulating layer; forming an intermediate layer on the source and drain electrodes; and forming an organic semiconductor layer to be electrically connected to the source and drain electrodes; wherein the intermediate layer includes a first layer which reduces the contact resistance between the organic semiconductor layer and the source and drain electrodes, and a second layer which facilitates growth of the organic semiconductor crystals of the organic semiconductor layer. Thus, a TFT, such as the TFT 10 of FIG. 3 or FIG. 4, may be manufactured.

Each layer mentioned in the description of the above methods of manufacturing the TFTs according to the embodiments of the present invention is described above, and thus a detailed description thereof will be omitted.

When the source and drain electrodes include an oxidizable metal, the forming of the source and drain electrodes may further include oxidizing surfaces of the source and drain electrodes. This operation is performed in order to increase the adhesive force between the source and drain electrodes and the intermediate layer, which is formed after the source and drain electrodes are formed.

The oxidizing the surfaces of the source and drain electrodes can be implemented using a variety of methods. For example, a method of annealing the surfaces of the source and drain electrodes under atmospheric conditions, for example, in an oxygen atmosphere, a method of treating the surfaces of the source and drain electrodes with a gas, for example, oxygen plasma, a method of chemically treating the surfaces of the source and drain electrodes with an oxidant, for example, hydrogen peroxide, or other methods can be used. However, the methods used to oxidize the surfaces of the source and drain electrodes are not limited to the latter method.

The forming of the intermediate layer is performed by forming the first layer on the source and drain electrodes, and forming the second layer on the first layer.

The forming of the first layer, which reduces the contact resistance between the organic semiconductor layer and the source and drain electrodes, may be performed by: a well-known deposition method; a well-known coating method such as spin coating, dip coating, micro contact printing or inkjet printing; or a well-known method of forming SAM. In the method of forming SAM, a catalyst that can assist the reaction, for example, hydrolysis or condensation, for forming the first layer can be further used.

The forming of the second layer, which facilitates growth of the organic semiconductor crystals of the organic semiconductor layer, may be performed by coating and heat-treating a mixture including a solvent and an organic semiconductor crystal growth-facilitating material, such as PMMA and PS, as mentioned above.

The solvent may be a conventional polar solvent, such as water, methanol, ethanol, acetic acid, or the like, but is not limited thereto.

The concentration of the mixture may be 0.1 wt % thru 1 wt %; or 0.1 wt % thru 0.5 wt % preferably. When the concentration of the mixture is equal to or greater than 0.1 wt %, the second layer may be formed effectively. When the concentration of the mixture is equal to or less than 1 wt %, the second layer, which facilitates growth of the organic semiconductor crystals of the organic semiconductor layer, may be formed effectively as thin as mentioned above.

After the mixture is coated on the first layer, the mixture should be heat-treated at a sufficiently high temperature to volatilize the solvent. The temperature may be varied according to the solvent being used, but may be, for example, between 100° C. and 120° C.

A TFT having the above-described structure may be included in a flat panel display device, such as an LCD or an organic light emission display device.

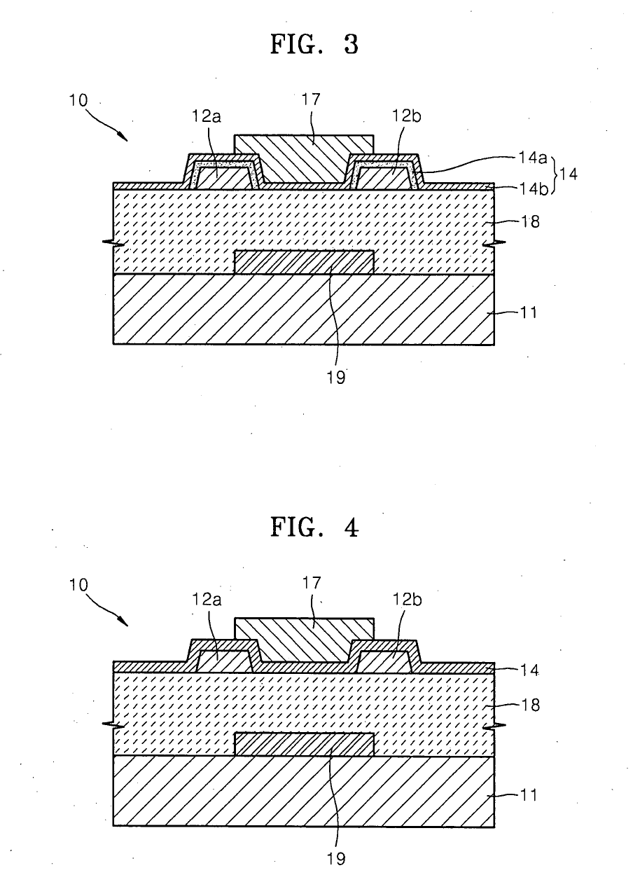

FIG. 5 is a cross-sectional view illustrating an organic light emitting display device including a TFT according to an embodiment of the present invention.

The TFT 20 of FIG. 5 is one sub-pixel of the organic light emitting display device. Each sub-pixel of the organic light emission display device includes an organic light-emitting device 30 as a self-emissive device and at least one TFT.

The organic light-emitting display device includes various pixel patterns, preferably, red, green and blue pixels, according to a luminescent color of the organic light-emitting device 30.

Referring to FIG. 5, source and drain electrodes 22a and 22b, respectively, having a predetermined pattern are formed on a substrate 21, and an intermediate layer 24 is formed so as to cover the source and drain electrodes 22a and 22b, respectively. The intermediate layer 24 includes a first layer 24a which reduces the contact resistance between an organic semiconductor layer 27 and the source and drain electrodes 22a and 22b, respectively, and a second layer 24b which facilitates growth of organic semiconductor crystals of the organic semiconductor layer 27. Unlike FIG. 5, an interface may not be apparent between the first and the second layer 24a and 24b, respectively. An insulating layer 28 is formed so as to cover the organic semiconductor layer 27. A gate electrode 29 is formed so as to correspond to the source and drain electrodes 22a and 22b, respectively. Each layer included in the TFT 20 corresponds to an equivalent layer in the TFT 10 of the previous embodiments, and thus a detailed description thereof will be omitted.

After the gate electrode 29 is formed, a passivation layer 31 is formed so as to cover the TFT 20. The passivation layer 31 is formed as a single-layered or multi-layered structure, and may be formed of an organic material, an inorganic material or an organic/inorganic composite material.

A pixel-defining layer 33, which defines a pixel, is formed on the passivation layer 31. An organic layer 36 of the organic light-emitting device 30 is formed on an opening 33a of the pixel-defining layer 33.

The organic light-emitting device 30 displays predetermined image information by emitting red, green and blue light according to the flow of a current. The organic light-emitting device 30 includes a pixel electrode 35 connected to one of the source and drain electrodes 22a and 22b, respectively, a facing electrode 38 covering the entire surface of a pixel, and the organic layer 36 interposed between the pixel electrode 35 and the facing electrode 38. The present invention is not limited to the structure illustrated in FIG. 5, and various structures of organic light emission display devices can be applied.

The organic layer 36 may be a small-molecular weight organic layer or a polymer organic layer. When the organic layer 36 is a small-molecular weight organic layer, the organic layer 36 may have a structure including one or combinations of a hole injection layer (HIL), a hole transport layer (HTL), an emission layer (EML), an electron transport layer (ETL) and an electron injection layer (EIL). Examples of organic materials for the small-molecular weight organic layer include copper phthalocyanine (CuPc), N,N-di(naphthalene-1-yl)-N,N′-diphenyl-benzidine (NPB), tris-8-hydroxyquinoline aluminum (Alq3), etc. The small-molecular weight organic layer can be formed using, for example, vacuum deposition.

When the organic layer 36 is a polymer organic layer, the organic layer 36 may have a structure including an HTL and an EML. The HTL may be formed of poly-3,4-ethylenedioxythiophene (PEDOT) and the EML may be formed of a poly-phenylenevinylene (PPV)-based or polyfluorene-based polymer material using screen printing, inkjet printing, etc.

The organic layer 36 is not limited to the above-described organic layers, and may have various structures.

The pixel electrode 35 may act as an anode, and the facing electrode 38 may act as a cathode. Alternatively, the polarities of the pixel electrode 35 and the facing electrode 38 may be reversed.

Unlike organic light emission display devices, a method of manufacturing an LCD further includes forming a lower substrate by forming a lower alignment layer (not shown) covering the pixel electrode 35.

The TFT 20 according to the current embodiment of the present invention can be installed in each sub-pixel as illustrated in FIG. 5, or in a driver circuit (not shown) where no image is formed.

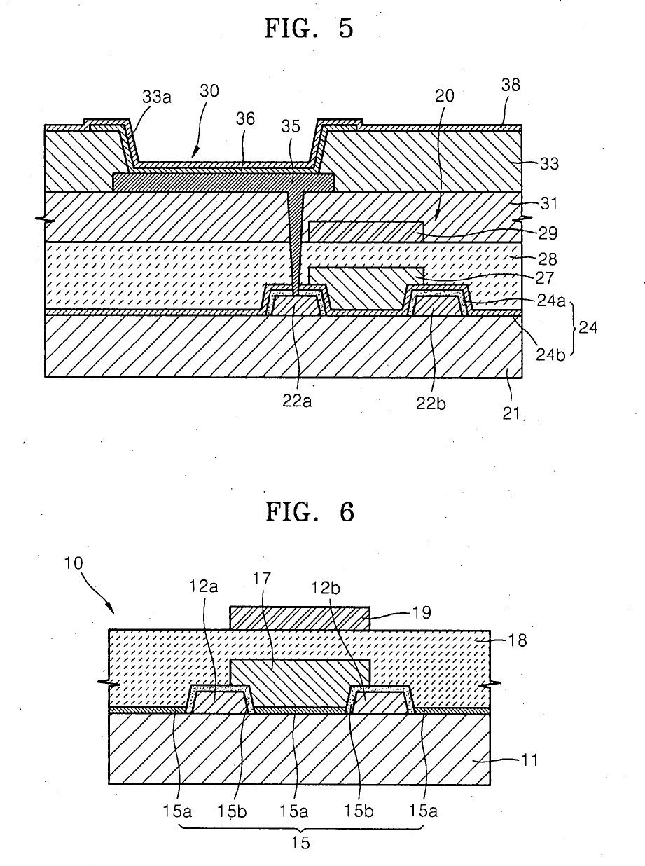

FIG. 6 is a cross-sectional view of a TFT according to an embodiment of the present invention.

Referring to FIG. 6, the TFT 40 includes a substrate 41, source and drain electrodes 42a and 42b, respectively, an intermediate layer 44, an organic semiconductor layer 47, an insulating layer 48 and a gate electrode 49 which are stacked upon one another in the above-described order. The intermediate layer 44 includes a plurality of first regions 44a which facilitate growth of organic semiconductor crystals of the organic semiconductor layer 47, and a plurality of second regions 44b which reduce the contact resistance between the organic semiconductor layer 47 and the source and drain electrodes 42a and 42b, respectively. The substrate 41, the source and drain electrodes 42a and 42b, respectively, the organic semiconductor layer 47, the insulating layer 48 and the gate electrode 49 are described above, and thus detailed descriptions thereof will be omitted.

The organic semiconductor layer 47 is formed on the source and drain electrodes 42a and 42b, respectively, so as to be electrically connected to the source and drain electrodes 42a and 42b, respectively. The intermediate layer 44 is interposed between the organic semiconductor layer 47 and the source and drain electrodes 42a and 42b, respectively. The intermediate layer 44 includes the first regions 44a which facilitate growth of the organic semiconductor crystals of the organic semiconductor layer 47, and the second regions 44b which reduce the contact resistance between the organic semiconductor layer 47 and the source and drain electrodes 42a and 42b, respectively.

According to the current embodiment of the present invention, the second regions 44b of the intermediate layer 44 can be formed so as to cover the source and drain electrodes 42a and 42b, respectively, but are not limited thereto.

The intermediate layer 44 can be formed so as to have a thickness between 10 Å and 100 Å. When the thickness of the intermediate layer 44 is equal to or greater than 10 Å, organic semiconductor crystals can be grown satisfactorily. When the thickness of the intermediate layer 44 is equal to or less than 100 Å, the organic semiconductor 47 can be electrically connected with the source and drain electrodes 42a and 42b, respectively.

The first regions 44a of the intermediate layer 44 facilitate growth of the organic semiconductor crystals of the organic semiconductor layer 47. The organic semiconductor layer 47 is formed on the intermediate layer 44. When the organic semiconductor crystals of the organic semiconductor layer 47 are small, resistance can be increased as the grain boundary of the crystalline structure gets larger and the number of trap sites increases. However, when the organic semiconductor layer 47 is formed on the intermediate layer 44 including the first regions 44a according to the current embodiment of the present invention, the organic semiconductor crystals can be grown satisfactorily, and electrical properties of the TFT 40 can be improved.

A contact angle of water on the first regions 44a of the intermediate layer 44 is greater than a contact angle of water on the source and drain electrodes 42a and 42b, respectively. Thus, the organic semiconductor crystals on the first regions 44a can be grown satisfactorily due to a principle of different surface energies of a metal and an organic material. The contact angle is described above, and thus a detailed description thereof will be omitted.

Throughout this specification, the contact angle of water on the first regions 44a or the source and drain electrodes 42a and 42, respectively, b refers to the measured contact angle of a liquid, which is water, on a solid plane surface, in this case, the first regions 44a or the source and drain electrodes 42a and 42b, respectively. According to an embodiment of the present invention, contact angles of water on the first regions 44a and the source and drain electrodes 42a and 42b, respectively, may be measured, for example, using a contact angle method using water as described above.

The contact angle of water on the first regions 44a of the intermediate layer 44 is greater than the contact angle of water on the source and drain electrodes 42a and 42b, respectively. More particularly, the contact angle of water on the first regions 44a may be 10° thru 15° greater than the contact angle of water on the source and drain electrodes 42a and 42b, respectively. When the contact angle of water on the first regions 44a is at least 10° greater than the contact angle of water on the source and drain electrodes 42a and 42b, respectively, the organic semiconductor crystals can be grown satisfactorily. When the contact angle of water on the first regions 44a is at most 15° greater than the contact angle of water on the source and drain electrodes 42a and 42b, respectively, excellent electrical properties of the TFT 40 can be achieved.

More particularly, the first regions 44a of the intermediate layer 44 may include at least one selected from a group consisting of PMMA and PS, but are not limited thereto.

The second regions 44b of the intermediate layer 44 reduce the contact resistance between the organic semiconductor layer 47 and the source and drain electrodes 42a and 42b, respectively. The second regions 44b of the intermediate layer 44 may include a contact-resistance reducing material. The second regions 44b of the intermediate layer 44 may also include the contact-resistance reducing material and a material included in the first regions 44a of the intermediate layer 44.

A material included in the second regions 44b of the intermediate layer 44, such as the contact-resistance reducing material, may be one of a plurality of well-known materials which can reduce the contact resistance between the organic semiconductor layer 47 and the source and drain electrodes 42a and 42b, respectively. For example, the contact-resistance reducing material may be a material included in SAM. More particularly, the contact-resistance reducing material can be MNB or MMB, but is not limited thereto.

According to an embodiment of the present invention, the first regions 44a of the intermediate layer 44 which facilitates growth of the organic semiconductor crystals can include PMMA, and the second regions 44b which reduces the contact resistance between the organic semiconductor layer 47 and the source and drain electrodes 42a and 42b can include MNB. Otherwise, the first regions 44a of the intermediate layer 44 which facilitate growth of the organic semiconductor crystals can include PMMA, and the second regions 44b which reduce the contact resistance between the organic semiconductor layer 47 and the source and drain electrodes 42a and 42b, respectively, can include PMMA and MNB. However, the present invention is not limited thereto.

According to another embodiment of the present invention, the first regions 44a of the intermediate layer 44 which facilitate growth of the organic semiconductor crystals can include PMMA, and the second regions 44b which reduce the contact resistance between the organic semiconductor layer 47 and the source and drain electrodes 42a and 42b, respectively, can include MMB. Otherwise, the first regions 44a of the intermediate layer 44 which facilitate growth of the organic semiconductor crystals can include PMMA, and the second regions 44b which reduce the contact resistance between the organic semiconductor layer 47 and the source and drain electrodes 42a and 42b, respectively, can include PMMA and MMB. However, the present invention is not limited thereto.

For example, when the source and drain electrodes 42a and 42b, respectively, are formed of Au, the contact angle of water on the source and drain electrodes 42a and 42b, respectively, is 60° thru 80°. When the first regions 44a of the intermediate layer 44 include PMMA, the contact angle of water on the first regions 44a may be 70° thru 90°.

The organic semiconductor layer 47 and the source and drain electrodes 42a and 42b, respectively, are electrically connected to each other, and are formed on the above-described intermediate layer 44, including the first and second regions 44a and 44b, respectively.

FIG. 7 is a cross-sectional view of a TFT according to another embodiment of the present invention.

Referring to FIG. 7, the TFT 40 includes a substrate 41, a gate electrode 49, an insulating layer 48, source and drain electrodes 42a and 42b, respectively, an intermediate layer 44 and an organic semiconductor layer 47 which are stacked upon one another in the above-described order. The intermediate layer 44 includes a plurality of first regions 44a which facilitate growth of organic semiconductor crystals of the organic semiconductor layer 47, and a plurality of second regions 44b which reduce the contact resistance between the organic semiconductor layer 47 and the source and drain electrodes 42a and 42b, respectively.

Each layer included in the TFT 40 of FIG. 7 corresponds to its equivalent layer in the TFT 40 of FIG. 6, and thus a detailed description thereof will be omitted.

A TFT according to the present invention can be manufactured using a variety of methods.

A method of manufacturing the TFT according to another embodiment of the present invention may include: forming source and drain electrodes on a substrate; forming an intermediate layer so as to cover the source and drain electrodes; forming an organic semiconductor layer on the intermediate layer; forming an insulating layer so as to cover the organic semiconductor layer; and forming a gate electrode so as to correspond to the source and drain electrodes; wherein the intermediate layer includes a plurality of first regions which facilitate growth of organic semiconductor crystals of the organic semiconductor layer, and a plurality of second regions which reduce the contact resistance between the organic semiconductor layer and the source and drain electrodes. Thus, a TFT, such as the TFT 40 of FIG. 6, may be manufactured.

A method of manufacturing the TFT according to another embodiment of the present invention may include: forming a gate electrode on a substrate; forming an insulating layer so as to cover the gate electrode; forming source and drain electrodes on the insulating layer; forming an intermediate layer so as to cover the source and drain electrodes; and forming an organic semiconductor layer on the intermediate layer; wherein the intermediate layer includes a plurality of first regions which facilitate growth of organic semiconductor crystals of the organic semiconductor layer, and a plurality of second regions which reduce the contact resistance between the organic semiconductor layer and the source and drain electrodes. Thus, a TFT, such as the TFT 40 of FIG. 7, may be manufactured.

Each layer mentioned in the description of the above methods of manufacturing the TFTs according to the embodiments of the present invention is described above, and thus a detailed description thereof will be omitted.

When the source and drain electrodes include an oxidizable metal, the forming of the source and drain electrodes may further include oxidizing surfaces of the source and drain electrodes. This operation is performed in order to increase the adhesive force between the source and drain electrodes and the second regions of the intermediate layer, which is formed after the source and drain electrodes are formed.

The oxidizing the surfaces of the source and drain electrodes can be implemented using a variety of methods. For example, a method of annealing the surfaces of the source and drain electrodes under atmospheric conditions, for example, in an oxygen atmosphere, a method of treating the surfaces of the source and drain electrodes with a gas, for example, oxygen plasma, a method of chemically treating the surfaces of the source and drain electrodes with an oxidant, for example, hydrogen peroxide, or other methods can be used. However, the methods that can be used to oxidize the surfaces of the source and drain electrodes are not limited to the latter methods.

The forming of the intermediate layer may be performed by coating a first mixture, including an organic semiconductor crystal-growth facilitating material, on the source and drain electrodes and heat-treating the first mixture, and coating a second mixture, including a contact-resistance reducing material, on the resultant obtained by the coating and heat-treating of the first mixture, and heat-treating the second mixture. The organic semiconductor crystal-growth facilitating material may be PMMA, PS or the like, on which the contact angle of water is in the above-described range. The contact-resistance reducing material may be MNB, MMB or the like.

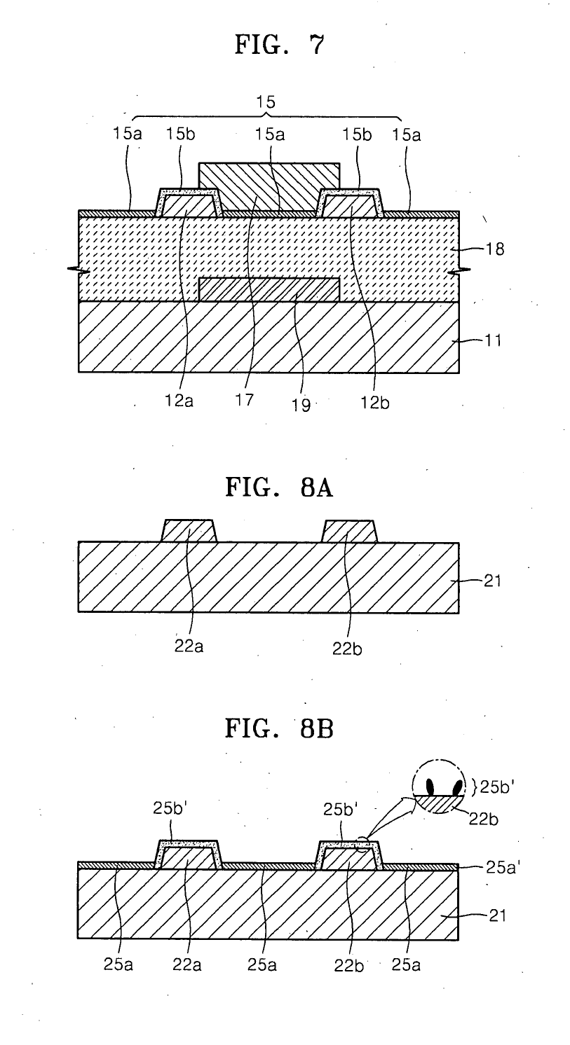

FIGS. 8A thru 8C are cross-sectional views illustrating a method of manufacturing an intermediate layer of a TFT according to an embodiment of the present invention.

Referring to FIG. 8A, a substrate 41 including source and drain electrodes 42a and 42b, respectively, is prepared.

Referring to FIG. 8B, a first mixture layer 44a′ is formed by coating a first mixture, including an organic semiconductor crystal-growth facilitating material, so as to cover the source and drain electrodes 42a and 42b, respectively, and heat-treating the first mixture. Here, the first mixture layer 44a′ includes a plurality of first regions 44a which facilitate growth of organic semiconductor crystals and a plurality of regions 44b′ sporadically including the organic semiconductor crystal-growth facilitating material. As shown in an enlarged drawing of the regions 44b′, of FIG. 8B, the organic semiconductor crystal-growth facilitating material is not coated, or is sporadically coated, on the source and drain electrodes 42a and 42b, respectively, thereby not forming a continuous layer. Accordingly, some parts of surfaces of the source and drain electrodes 42a and 42b, respectively, can be exposed on the regions 44b′ on which the organic semiconductor crystal-growth facilitating material is sporadically coated.

Referring to FIG. 8C, a second mixture including a contact-resistance reducing material is coated on the regions 44b′ of the first mixture layer 44a′, and then the second mixture is heat treated. When the second mixture, including the contact-resistance reducing material, is coated on the regions 44b′ sporadically including the organic semiconductor crystal-growth facilitating material of the first mixture layer 44a′, the contact-resistance reducing material can be coated on exposed parts of the source and drain electrodes 42a and 42b, respectively, as shown in an enlarged drawing of the regions 44b′ of FIG. 8C. Accordingly, a plurality of second regions 44b, which includes only the contact-resistance reducing material, or which includes both the organic semiconductor crystal-growth facilitating material and the contact-resistance reducing material, can be formed. As a result, the intermediate layer, including the first regions 44a which facilitate growth of the organic semiconductor crystals and the second regions 44b which reduce the contact resistance, is formed.

The first mixture, including the organic semiconductor crystal-growth facilitating material, may further include a solvent. The solvent may be one of well-known polar solvents, for example, alcohol such as methanol and ethanol, water and acetic acid, but it is not limited thereto.

The concentration of the first mixture may be 0.1 wt % thru 1 wt %. When the concentration of the first mixture is greater than 0.1 wt %, organic semiconductor crystals may be grown satisfactorily. When the concentration of the first mixture is less than 1 wt %, the intermediate layer may be formed as thin as described above.

After the first mixture is coated, the first mixture should be heat treated at a sufficiently high temperature to volatilize the solvent included in the first mixture. The temperature may be varied according to the solvent being used, but may be, for example, between 100° C. and 120° C.

The second mixture may include, for example, a material included in SAM, such as at least one of MNB and MMB. The heat-treating temperature of the second mixture after the second mixture is coated may be determined by one of ordinary skill in the art according to the selected material included in SAM.

A TFT having the above-described structure may be included in a flat panel display device, such as an LCD or an organic light emission display device.

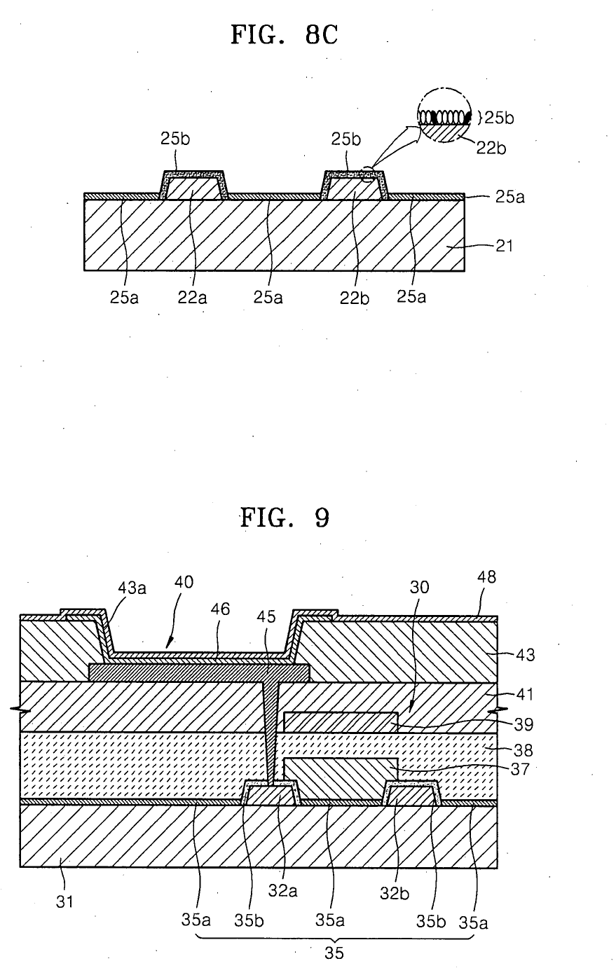

FIG. 9 is a cross-sectional view of an organic light emission display device including a TFT according to another embodiment of the present invention.

The TFT 50 of FIG. 9 is one sub-pixel of the organic light emitting display device. Each sub-pixel of the organic light emission display device includes an organic light-emitting device 60 as a self-emissive element and at least one TFT 50.

Referring to FIG. 9, source and drain electrodes 52a and 52b, respectively, having a predetermined pattern are formed on a substrate 51, and an intermediate layer 54 is formed so as to cover the source and drain electrodes 52a and 52b, respectively. An organic semiconductor layer 57 is formed on the intermediate layer 54. The intermediate layer 54 includes a plurality of first regions 54a which facilitate growth of organic semiconductor crystals, and a plurality of second regions 54b which reduce contact resistance between the organic semiconductor layer 57 and the source and drain electrodes 52a and 52b, respectively. An insulating layer 58 is formed so as to cover the organic semiconductor layer 57. A gate electrode 59 is formed so as to correspond to the source and drain electrodes 52a and 52b, respectively. Each layer included in the TFT 50 corresponds to an equivalent layer in the TFT 10 or 40 of the previous embodiments, and thus a detailed description thereof will be omitted.

After the gate electrode 59 is formed, a passivation layer 61 is formed so as to cover the TFT 50. The passivation layer 61 is formed as a single-layered or multi-layered structure, and may be formed of an organic material, an inorganic material or an organic/inorganic composite material.

A pixel-defining layer 63, which defines a pixel, is formed on the passivation layer 61. An organic layer 66 of the organic light-emitting device 60 is formed on an opening 63a of the pixel-defining layer 63.

The organic light-emitting device 60 displays predetermined image information by emitting red, green and blue light according to the flow of a current. The organic light-emitting device 60 includes a pixel electrode 65 connected to one of the source and drain electrodes 52a and 52b, respectively, a facing electrode 68 covering the entire surface of a pixel, and the organic layer 66 interposed between the pixel electrode 65 and the facing electrode 68. The present invention is not limited to the structure illustrated in FIG. 9, and various structures of organic light emission display devices can be applied. The organic light-emitting device 60 is described above, and thus a detailed description thereof will be omitted.

The present invention will be described in further detail with reference to the following examples. These examples are for illustrative purposes only, and are not intended to limit the scope of the present invention.

### EXAMPLES

### Example 1

A glass substrate including source and drain electrodes formed of Au was prepared. 0.02 wt % MNB solution (in an ethanol solvent) was spin-coated on the source and drain electrodes and was heat-treated at 100° C. so as to form a first layer which reduced the contact resistance between an organic semiconductor layer and the source and drain electrodes. Next, 0.5 wt % PMMA solution (Mw=950,000 g/mol, methanol solvent, manufactured by Sigma-Aldrich) was spin-coated on the first layer and was heat-treated at 100° C. so as to form a second layer (100 Å thick) which facilitated growth of organic semiconductor crystals of the organic semiconductor layer. Next, the organic semiconductor layer was formed by vapor-depositing pentacene on the intermediate layer so as to be electrically connected to the source and drain electrodes. An insulating layer was formed so as to cover the organic semiconductor layer. A gate electrode formed of MoW was formed on the insulating layer so as to be 100 nm thick. As a result, an organic TFT according to the present invention was manufactured. This TFT is referred to as [Sample 1].

### Comparative Example 1

Another organic TFT was formed using Example 1 described above, except that the second layer was not formed. This TFT is referred to as [Sample A].

Evaluation 1

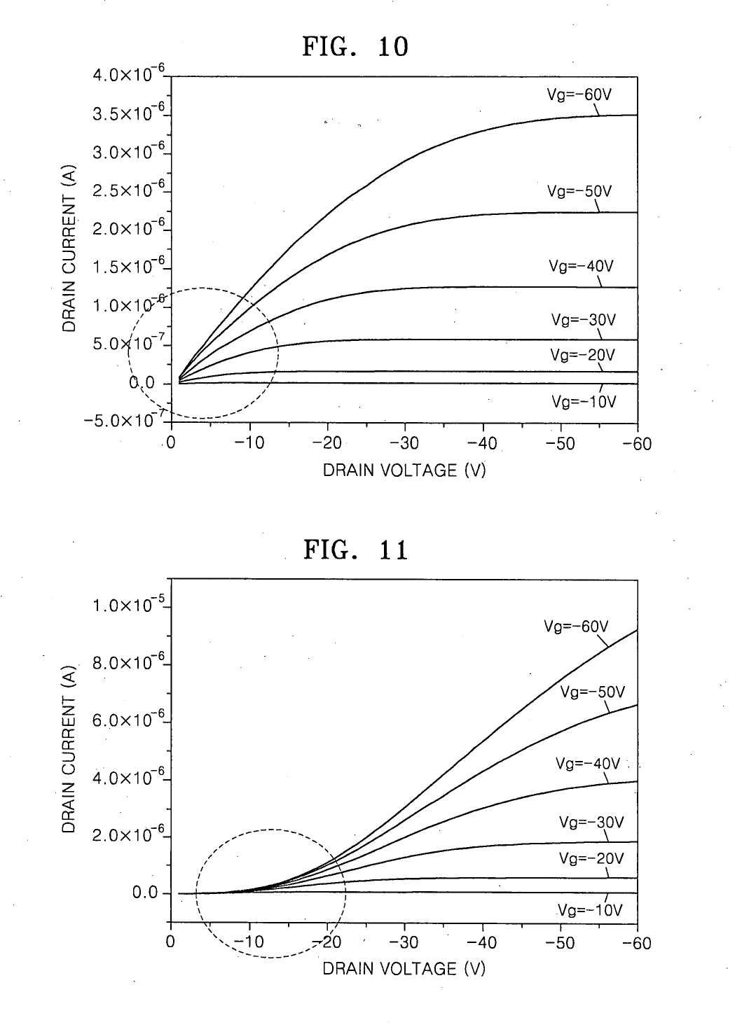

Current-voltage characteristics were evaluated for Sample 1 and Sample A. Agilent I-V Measuring Equipment (Model: 4156C) was used for the evaluation of the current-voltage characteristics. FIGS. 10 and 11 are graphs illustrating the current-voltage characteristics of Sample 1 and Sample A, respectively. Referring to FIGS. 10 and 11, it can be seen that the TFT according to the present invention, that is, Sample 1, has excellent electrical properties in comparison with the conventional TFT, that is, Sample A. For example, the contact resistance in the TFT according to the present invention is lower than that of the conventional TFT.

### Example 2

A glass substrate including source and drain electrodes formed of Au was prepared. 0.5 wt % PMMA solution (Mw=750,000 g/mol, methanol solvent, manufactured by Sigma-Aldrich) was spin-coated on the source and drain electrodes, and was heat-treated at 100° C. The spin-coated and heat-treated substrate was dipped in 0.02 wt % MNB solution (in an ethanol solvent), and was heat-treated at 100° C. Thus, an intermediate layer, including a plurality of first regions which facilitate growth of organic semiconductor crystals and a plurality of second regions which reduce contact resistance, was formed so as to be 1 nm thick. Next, an organic semiconductor layer was formed by vapor-depositing pentacene on the intermediate layer so as to be electrically connected to the source and drain electrodes. An insulating layer was formed so as to cover the organic semiconductor layer. A gate electrode formed of MoW was formed on the insulating layer so as to be 100 nm thick. As a result, an organic TFT according to the present invention was manufactured. This example is referred to as [Sample 2].

### Example 3

Another organic TFT was formed using Example 2 described above, except that the intermediate layer was formed so as to be 100 Å thick, not 1 nm thick. This example is referred to as [Sample 3].

### Comparative Example 2

Another organic TFT was formed using Process 2 described above, except that the intermediate layer was not formed. This example is referred to as [Sample B].

Evaluation 2

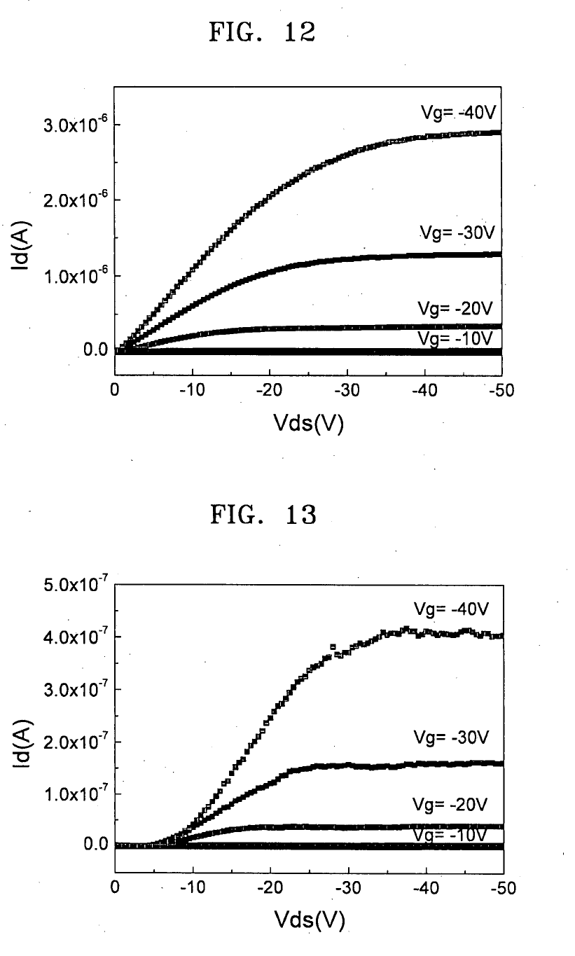

Current-voltage characteristics were evaluated for Sample 2 and Sample B. Agilent I-V Measuring Equipment (Model: 4156C) was used for the evaluation of the current-voltage characteristics. FIGS. 12 and 13 are graphs illustrating the current-voltage characteristics of Sample 2 and Sample B, respectively. Referring to FIGS. 12 and 13, it can be seen that the TFT according to the present invention, that is, Sample 2, has excellent electrical properties in comparison with the conventional TFT, that is, Sample B.

As described above, in a TFT according to the present invention, the contact resistance is lowered between the organic semiconductor layer and the source and drain electrodes. In addition, organic semiconductor crystals of the organic semiconductor layer are grown satisfactorily. Therefore, the TFT may have excellent electrical properties. Thus, a flat panel display device with improved reliability can be realized using the TFT.

While the present invention has been particularly shown and described with reference to exemplary embodiments thereof, it will be understood by those of ordinary skill in the art that various changes in form and detail may be made therein without departing from the spirit and scope of the invention as defined by the appended claims. The exemplary embodiments should be considered in descriptive sense only, and not for the purposes of limitation. Therefore, the scope of the invention is defined not by the detailed description of the invention, but by the appended claims, and all differences within the scope will be construed as being included in the present invention.

What is claimed is:

1. A thin film transistor, comprising:
a gate electrode;
source and drain electrodes insulated from the gate electrode;
an organic semiconductor layer which is insulated from the gate electrode, and which is electrically connected to the source and drain electrodes;
an insulating layer which insulates the gate electrode from one of the source and drain electrodes and the organic semiconductor layer; and
an intermediate layer formed between the organic semiconductor layer and the source and drain electrodes;
wherein the intermediate layer comprises a first layer which reduce the contact resistance between the organic semiconductor layer and the source and drain electrodes, and a second layer which facilitates growth of organic semiconductor crystals of the organic semiconductor layer.

2. The thin film transistor of claim 1, wherein the second layer has a thickness in a range of 10 Å-100 Å.

3. The thin film transistor of claim 1, wherein a contact angle of water on the second layer is greater than a contact angle of water on the source and drain electrodes.

4. The thin film transistor of claim 1, wherein the contact angle of water on the second layer is in a range of 10°-15° greater than a contact angle of water on the source and drain electrodes.

5. The thin film transistor of claim 1, wherein a contact angle of water on the second layer is in a range of 70°-80°.

6. The thin film transistor of claim 1, wherein the second layer comprises at least one of polymethylmethacrylate (PMMA) and polystyrene (PS).

7. The thin film transistor of claim 1, wherein the first layer is a self-assembled monolayer (SAM).

8. A flat panel display device comprising the thin film transistor of claim 1, the thin film transistor being disposed on each of a plurality of pixels, the flat panel display further comprising a pixel electrode contacting one of a source electrode and a drain electrode of the thin film transistor.

9. A method of manufacturing a thin film transistor, comprising the steps of:
forming source and drain electrodes on a substrate;
forming an intermediate layer on the source and drain electrodes;
forming an organic semiconductor layer so as to be electrically connected to the source and drain electrodes;
forming an insulating layer so as to cover the organic semiconductor layer; and
forming a gate electrode so as to correspond to the source and drain electrodes;
wherein the intermediate layer comprises a first layer which reduces a contact resistance between the organic semiconductor layer and the source and drain electrodes, and a second layer which facilitates growth of organic semiconductor crystals of the organic semiconductor layer.

10. The method of claim 9, wherein the second layer has a thickness in a range of 10 Å-100 Å.

11. The method of claim 9, wherein the second layer is formed by coating a mixture comprising a solvent and an organic semiconductor crystal growth-facilitating material on the first layer, and heat-treating the mixture.

12. The method of claim 11, wherein the mixture has a concentration in a range of 0.1 wt %-1 wt %.

13. A method of manufacturing a thin film transistor, comprising the steps of:
forming a gate electrode on a substrate;
forming an insulating layer so as to cover the gate electrode;
forming source and drain electrodes on the insulating layer;
forming an intermediate layer on the source and drain electrodes; and
forming an organic semiconductor layer so as to be electrically connected to the source and drain electrodes;
wherein the intermediate layer comprises a first layer which reduces a contact resistance between the organic semiconductor layer and the source and drain electrodes, and a second layer which facilitates growth of organic semiconductor crystals of the organic semiconductor layer.

14. The method of claim 13, wherein the second layer has a thickness in a range of 10 Å-100 Å.

15. The method of claim 13, wherein the second layer is formed by coating a mixture comprising a solvent and an organic semiconductor crystal growth-facilitating material on the first layer, and heat-treating the mixture.

16. The method of claim 15, wherein the mixture has a concentration in a range of 0.1 wt %-1 wt %.

17. A thin film transistor, comprising:
a gate electrode;
source and drain electrodes insulated from the gate electrode;
an organic semiconductor layer which is insulated from the gate electrode, and which is electrically connected to the source and drain electrodes;
an insulating layer which insulates the gate electrode from one of the source and drain electrodes and the organic semiconductor layer; and
an intermediate layer comprising a plurality of first regions which facilitate growth of organic semiconductor crystals of the organic semiconductor layer, and a plurality of second regions which reduce a contact resistance between the organic semiconductor layer and the source and drain electrodes.

18. The thin film transistor of claim 17, wherein the second regions of the intermediate layer are formed so as to cover the source and drain electrodes.

19. The thin film transistor of claim 17, wherein the intermediate layer has a thickness in a range of 10 Å-100 Å.

20. The thin film transistor of claim 17, wherein a contact angle of water on the first regions of the intermediate layer is greater than a contact angle of water on the source and drain electrodes.

21. The thin film transistor of claim 17, wherein a contact angle of water on the first regions of the intermediate layer is in a range of 10°-15° greater than a contact angle of water on the source and drain electrodes.

22. The thin film transistor of claim 17, wherein the first regions of the intermediate layer comprise at least one of PMMA and PS.

23. The thin film transistor of claim 17, wherein the second regions of the intermediate layer comprise a contact-resistance reducing material and a material included in the first regions of the intermediate layer.

24. The thin film transistor of claim 23, wherein the contact-resistance reducing material is a material included in SAM.

25. The thin film transistor of claim 17, wherein the second regions of the intermediate layer cover the source and drain electrodes, the first regions of the intermediate layer comprise PMMA, and the second regions of the intermediate layer comprise 2-mercapto-5-nitrobenzimidazole (MNB).

26. The thin film transistor of claim 17, wherein the second regions of the intermediate layer cover the source and drain electrodes, the first regions of the intermediate layer comprise PMMA, and the second regions of the intermediate layer comprise PMMA and MNB.

27. The thin film transistor of claim 17, wherein the second regions of the intermediate layer cover the source and drain electrodes, the first regions of the intermediate layer comprise PMMA, and the second regions of the intermediate layer comprise 2-mercapto-5-methoxy-benzimidazole (MMB).

28. The thin film transistor of claim 17, wherein the second regions of the intermediate layer cover the source and drain electrodes, the first regions of the intermediate layer comprise PMMA, and the second regions of the intermediate layer comprise PMMA and MMB.

29. A flat panel display device comprising the thin film transistor of claim 17, the thin film transistor being disposed on each of a plurality of pixels, the flat panel device further comprising a pixel electrode contacting one of a source electrode and a drain electrode of the thin film transistor.

30. A method of manufacturing a thin film transistor, comprising the steps of:
forming source and drain electrodes on a substrate;
forming an intermediate layer so as to cover the source and drain electrodes;
forming an organic semiconductor layer on the intermediate layer;
forming an insulating layer so as to cover the organic semiconductor layer; and
forming a gate electrode so as to correspond to the source and drain electrodes;
wherein the intermediate layer comprises a plurality of first regions which facilitate growth of organic semiconductor crystals of the organic semiconductor layer, and a plurality of second regions which reduce a contact resistance between the organic semiconductor layer and the source and drain electrodes.

31. The method of claim 30, wherein the intermediate layer has a thickness in a range of 10 Å-100 Å.

32. The method of claim 30, wherein the forming of the intermediate layer comprises coating a first mixture comprising an organic semiconductor crystal-growth facilitating material on the source and drain electrodes, and heat-treating the first mixture to form a resultant, coating a second mixture comprising a contact-resistance reducing material on the resultant, and heat-treating the second mixture.

33. The method of claim 32, wherein a concentration of the first mixture is in a range of 0.1 wt %-1 wt %.

34. A method of manufacturing a thin film transistor, comprising the steps of:
forming a gate electrode on a substrate;
forming an insulating layer so as to cover the gate electrode;
forming source and drain electrodes on the insulating layer;
forming an intermediate layer so as to cover the source and drain electrodes; and
forming an organic semiconductor layer on the intermediate layer;
wherein the intermediate layer comprises a plurality of first regions which facilitate growth of organic semiconductor crystals of the organic semiconductor layer, and a plurality of second regions which reduce a contact resistance between the organic semiconductor layer and the source and drain electrodes.

35. The method of claim 34, wherein the intermediate layer has a thickness in a range of 10 Å-100 Å.

36. The method of claim 34, wherein the forming of the intermediate layer comprises coating a first mixture comprising an organic semiconductor crystal-growth facilitating material on the source and drain electrodes, and heat-treating the first mixture to form a resultant, coating a second mixture comprising a contact-resistance reducing material on the resultant, and heat-treating the second mixture.

37. The method of claim 36, wherein a concentration of the first mixture is in a range of 0.1 wt %-1 wt %.
